(19) United States
(12) Patent Application Publication
(10) Pub. No.: US 2012/0183009 A1
(43) Pub. Date: Jul. 19, 2012

(54) HORIZONTAL CAVITY SURFACE EMITTING LASER DIODES, VERTICAL ILLUMINATED PHOTODIODES, AND METHODS OF THEIR FABRICATION

(75) Inventors: Koichiro ADACHI, Musashino (JP); Yasunobu MATSUOKA, Hachioji (JP); Toshiki SUGAWARA, Kokubunji (JP); Kazunori SHINODA, Musashino (JP); Shinji TSUJI, Hidaka (JP)

(73) Assignee: HITACHI, LTD.

(21) Appl. No.: 13/350,087

(22) Filed: Jan. 13, 2012

(30) Foreign Application Priority Data
Jan. 17, 2011 (JP) 2011-006630

(51) Int. Cl. H01S 3/08; H01L 21/02; G02B 6/12

(52) U.S. Cl. 372/99; 385/14; 438/31; 257/E21.002

(57) ABSTRACT

The horizontal cavity surface emitting laser includes a cavity structure portion including a stacked structure of a first conduction type clad layer, an active layer and a second conduction type clad layer stacked over a semiconductor substrate and causing light generated by the active layer to be reflected or resonated, an optical waveguide layer provided at part of the semiconductor substrate and guiding the light, a reflector provided in the optical waveguide layer, for reflecting the light and emitting the light from the back surface of the semiconductor substrate, and a condensing lens provided at the back surface thereof and focusing the reflected light. The back surface thereof has a groove provided with the condensing lens and a terrace-like portion disposed below the cavity structure portion and has a terrace shape with the cleavage direction along a longitudinal direction thereof provided along a cleavage direction of the semiconductor substrate.

### CLAIM OF PRIORITY

The present application claims priority from Japanese patent application JP 2011-006630 filed on Jan. 17, 2011, the content of which is hereby incorporated by reference into this application.

### BACKGROUND OF THE INVENTION

1. Field of the Invention

The present invention relates to a semiconductor laser device used in optical communications, and relates to, for example, a horizontal cavity surface emitting laser and a manufacturing method thereof, and a photodiode.

2. Description of the Related Arts

With the development of information technologies, the transmission of data using optical fiber communications has been rapidly developed. An optical fiber communication technology has heretofore mainly been used in long-distance high-speed data transmission typified by a land trunk line or a submarine optical communication, an access communication network typified by FTTH (Fiber To The Home), and a metro network that connects trunk lines and an access communication network. With an increase in the transmission capacity with the proliferation of Internet, the optical fiber communications have recently been spreading even to a storage network (SAN), Ethernet (Registered Trademark) (LAN) that connects among in-bureau high-speed network devices, etc. A communication protocol of a 100-Gbit Ethernet for transmitting 100 Gbits has been established on June, 2010 as an example of a next-generation optical LAN.

In recent years, per-device throughput of a high-end router used in a trunk line network has reached 1Tbps. A further capacity expansion has been expected form this time forward. With this capacity expansion, optical fiberization of wiring has been prospected to efficiently process large capacity data even at data transmission of an extremely short distance as in the case of between these transmission devices (a few m to a few hundred of m) or within a device (a few cm to a few tens of cm). Thus, while an increase in the capacity of a system has been advanced using light, a low cost technology will increasingly be an important challenge to provide data transmission using these at lower cost.

Under such a background, an improvement in high-speed performance and simple/high-density mountability becomes an important issue for a semiconductor optical element that performs transmission/reception of signals. This reason will be explained as below. While the speeding-up/increase in capacity of the system is progressing, the speeding up of a single optical device is facing a physical limit. Therefore, there arises a need to perform the transmission that has heretofore used a 1-channel signal, using plural channels. For example, it is assumed that such a configuration that 40 channels are used at 25 Gbs per channel and 1Tbps is transmitted, and the like are taken as throughput per board in a next-generation 10Tbps-class router. Thus, the high-speed semiconductor optical device excellent in high density and simple mountability, becomes one key device at a large-capacity system in the future. As a strong candidate of such an optical device, may be mentioned an array type device in which plural channels are monolithically integrated. The array device is advantageous in terms of a mounting area and the number of man-hour for work as compared with the case in which a device of a single channel is independently mounted. Since the interval between adjacent elements in the array device can be controlled with the accuracy of a semiconductor process, narrow pitching that exceeds a limit where the single channel is independently mounted, is made possible. As an index of a pitch interval, for example, the core interval between adjacent fibers is 250 μm in a commercialized ribbon fiber. In an organic substance polymer waveguide that has actively been developed in recent years, the core interval between respective channels is made possible with less than or equal to 120 μm or so. Since the narrow pitching is equivalent to a reduction in the device width, the utilization efficiency per wafer unit area can be increased. It can therefore be said that this is advantageous even in terms of device mass productivity.

Semiconductor laser devices each corresponding to this signal transmission light source are classified into three types according to how to combine their cavity directions (vertical resonance, horizontal resonance) and emitting surfaces of laser light (end face emission, plane or surface emission). The first type is of a horizontal cavity end face emitting laser device, the second type is of a vertical cavity surface emitting laser device, and the third type is of a horizontal cavity surface emitting laser device.

The first horizontal cavity end face emitting laser is formed with an optical waveguide in a substrate in-plane horizontal direction and emits laser light from end faces divided by cleavage of a substrate. Since the cavity length can be taken long up to a few hundred of μm in this laser structure, a high output of a few tens of mW is obtained even under a high temperature. It is however necessary to install an optical member for receiving the laser light adjacent to the laser device within the surface of a printed circuit board. This is not adequate to multichannel high-density mounting or miniaturization of the entire module.

Next, the second vertical cavity surface emitting laser is of a laser having a structure in which a resonator cavity is formed in the direction normal to a semiconductor substrate. Therefore, the layout of placing a photodetecting member on the device's top surface is possible. This is advantageous in higher densification within the surface of a printed circuit board. The present structure has, however, a problem that the cavity length is very long since it is determined by a crystal growth thickness, and it is essentially difficult to obtain a high optical output.

It can be said that the third horizontal cavity vertical surface emitting laser is of a laser structure which combines excellent points of the two lasers. In the present structure, a resonator cavity is formed in a substrate in-plane horizontal direction. In addition to this, the present structure has a structure in which a reflection mirror tilted to 45° is integratedly formed to emit laser light from the surface of the substrate or its back surface.

The present invention relates to the third horizontal cavity surface emitting laser. As an example of such a conventional horizontal cavity surface emitting laser, a horizontal cavity surface emitting laser having an active region of 10 through 100 μm, a distributed bragg reflector and a tilt mirror has been disclosed in Japanese Patent Application Laid-Open No. 2007-5594. Japanese Patent Application Laid-Open No. 2007-5594 has also disclosed an example in which a lens is integrated onto a light emitting surface.

Further, a configuration of a small module of a horizontal cavity surface emitting laser having an integrated lens has been disclosed in Japanese Patent Application Laid-Open No. 2010-147197. In the present known example, the shapes of the lens and mirror portion are contrived to make it possible to three-dimensionally place a monitor PD and a laser. A compact module is therefore possible. As a third known example, the normal-temperature continuous oscillation characteristics of a horizontal cavity surface emitting laser equipped with an optical waveguide including an InGaAsP active layer formed on an InP substrate, a reflector formed with an angle of 45° at the end of the optical waveguide, and a circular lens formed at a position opposite to the 45° reflector on the back surface of the InP substrate have been reported to IEEE PHOTONICS TECHNOLOGY LETTERS, VOL. 3, NO. 9, 1991, pp. 776-778.

As disclosed in these documents, in the horizontal cavity surface emitting laser in which light is emitted from the substrate surface in particular, the lens can be monolithically integrated on its corresponding light emitting surface with relative ease. Integrating the lens and the device as one makes it possible to reduce the number of parts like an external lens and members for supporting it. It is also possible to reduce the areas for placing these members in addition to the above. It can thus be said that an optical system for connecting an optical device and a photodetecting part can be brought into less size and hence this is a structure suitable for high-density packaging. This laser is advantageous in terms of alignment accuracy since the lens and the light emitting position can be controlled with the accuracy of a semiconductor process.

Further, a simple and small module configuration is made possible by setting such a lens-integration type horizontal cavity surface emitting laser to the array type, thus enabling higher densification. It can thus be said that the narrow pitch array type horizontal cavity surface emitting laser having the integrated lens is of a device suitable for the next-generation optical communications in terms of both transmission capacity and cost.

Any of the above Patent Documents does not however disclose a description about arraying of a lens integration type horizontal cavity surface emitting laser.

### SUMMARY OF THE INVENTION

As an example of a lens integration structure to a horizontal cavity surface emitting laser, there is considered either a structure integrated on the bottom of a recess (concave portion) of a circular form circular concentrically with such a lens as disclosed in Japanese Patent Application Laid-Open No. 2007-5594 (hereinafter referred to as Patent Document 1) and Japanese Patent Application Laid-Open No. 2010-147197 (hereinafter referred to as Patent Document 2), or a structure in which a lens disclosed in IEEE PHOTONICS TECHNOLOGY LETTERS, VOL. 3, NO. 9, 1991, pp. 776-778 (hereinafter referred to as Non-Patent Document 1) protrudes against a substrate surface. The structure disclosed in the Non-Patent Document 1 has however a problem in that during a semiconductor process and when a device is mounted to a module, the protruded lens may break due to its hit to an object or the like, and hence the yield is degraded at both device fabrication and module assembly. On the other hand, such a structure as disclosed in each of the Patent Documents 1 and 2 does not cause such a problem since the substrate surface around the lens protects the lens. Accordingly, the structures disclosed in the Patent Documents 1 and 2 are more suitable. A structure example of such a conventional horizontal cavity vertical surface emitting laser as disclosed in each of the Patent Documents 1 and 2 will be explained using FIGS. 1A and 1B. The structure of the present device will be described below.

FIG. 1A is a section of the device as viewed in an optical axis direction. The present device is formed on an n-type InP substrate 1001. Light is generated by injecting current from an n electrode 1006 at the back surface of the n-type InP substrate 1001 and a p electrode 1005 at the surface of the n-type InP substrate 1001 to an InGaAsP active layer 1002. The generated light propagates through a waveguide formed with a diffraction grating 1003 that periodically changes in refractive index. The light is fed back by the diffraction grating to thereby cause laser oscillations. The present laser is of a so-called distributed feedback (DFB) laser. The so-generated laser light is fully reflected by a 45° reflector 1008 formed by etching processing one end of the waveguide and introduced in the direction of a substrate back surface, followed by being emitted from a lens 1010 integrated on an emitting surface of the substrate back surface. After the device has been brought into chipping, although not shown in the drawing, the device is die-bonded onto a laser submount by AuSn solder with the existing surface of the p electrode 1005 as an adhesive surface. On the other hand, although not shown in the drawing, the n electrode is connected to ground using a gold wire having a diameter of 50μ. Incidentally, although the present example has showed the structure in which mounting is performed using the gold wire, even a flip-chip mounted structure is possible.

FIG. 1B is a mounting plan view of the device. Since a cavity is formed within a substrate surface in the horizontal cavity surface emitting laser having such a structure, a cavity length can be taken long and high output is easy. Since light is emitted perpendicular to the substrate surface, a photodetecting member can be placed in the upper surface of the device. Thus, the present device is advantageous even in high-density mounting. Since an integrated lens can be formed in a light emitting surface with relative ease, high-efficient optical coupling to an optical photodetecting system is possible. It can thus be said that the present device is a device excellent even in power saving and reduction in the number of parts of a module/its miniaturization.

As is understood from FIG. 1A, however, in the structures disclosed in such Patent Documents 1 and 2, a concave portion 1015 at which the lens is integrated, becomes thinner than other parts on the substrate. Therefore, when the present device is set to a narrow pitch array type suitable for high-density mounting, such problems on fabrication as will be descried below arise.

In the conventional lens integration type horizontal cavity surface emitting laser disclosed in each of the Patent Documents 1 and 2, when it is set as a narrow pitch array structure, i.e., each device width is reduced, the interval between the adjacent lenses becomes small, and the intervals among the concave portions at which the lenses are formed as shown in FIG. 1C also become close. That is, portions thin in wafer thickness are closely-arranged in row form and in the directions (aa, bb, cc, dd and ee directions in FIG. 1C) each parallel to a cleavage direction. Therefore, the device is not cleaved along aa indicative of a desired cleavage position but cleaved along the portions thin in wafer thickness as in the case of bb, cc, dd, ee, etc. A problem therefore arises in that the fabrication yield of the device is significantly degraded.

Incidentally, the present problem mainly relates to one peculiar to an optical device using a GaAs substrate and an InP substrate. If a sapphire substrate is taken as a typical substrate used in another optical device by way of example, this substrate is hard and hard to break as compared with GaAs, InP or the like in terms of its crystal property. Therefore, the cleavage for originally generating a crystal plane becomes difficult regardless of the presence or absence of a concavo-convex structure. In a device using silicon, the thickness of a substrate is about 600 μm or more, and the substrate is thick and hard to break with respect to 100 to 200 μm of a device using GaAs or InP. Further, devices using crystal planes by cleavage are almost none. In general, a chip division by dicing has been has been carried out.

On the other hand, the problem related to the present invention resides in that points easy to break up on the wafer newly occur due to the close integration of the lenses on GaAs or InP substrate, and therefore cleavage at a cleavage position desired to generate a crystal plane becomes difficult. That is, the problem about the hardness to break that occurs in sapphire and silicon results from the property of hardness that the original substrate has. This is different essentially and structurally from the problem related to the present invention that the hardness to break at a predetermined position occurs because the structure is provided.

As described above, the problems to be addressed by the present invention do not essentially arise in a device using sapphire or a silicon substrate. Therefore, the present invention mainly relates to an optical device using a GaAs or InP substrate.

Therefore, an object of the present invention is to provide a horizontal cavity surface emitting laser which is high in fabrication yield and excellent in high-density simple mountability.

A typical means for achieving the above object is shown below.

A horizontal cavity surface emitting laser of the present invention is equipped with a cavity structure portion which includes a stacked structure of a first conduction type clad layer, an active layer for generating light and a second conduction type clad layer stacked over a semiconductor substrate in this order, and which causes the generated light to be reflected or resonated in an in-plane direction; an optical waveguide layer which is provided at least part of the semiconductor substrate and guides the light generated from the active layer; a reflector provided at a part of the optical waveguide layer, for reflecting the light radiated from the cavity structure portion and emitting the light from the back surface of the semiconductor substrate; and a condensing lens which is provided in a light emitting region that corresponds to the back surface of the semiconductor substrate and causes the light to be emitted therefrom, and which focuses the light reflected by the reflector, wherein the back surface of the semiconductor substrate has a groove with the condensing lens provided at its bottom, and a terrace-like portion provided along the direction of cleavage of the semiconductor substrate, and wherein the terrace-like portion is disposed within a range in which a forming region of the cavity structure portion is extended downward, and has an open end on the lateral end side having a crystal plane formed by cleavage of the semiconductor substrate, a sidewall provided on the side opposite to the open end, and a terrace shape with the cleavage direction taken as a longitudinal direction thereof.

With such a configuration, a horizontal cavity surface emitting laser having a lens disposed with a narrow pitch is also capable of cleavage with satisfactory yields. Further, since a device width can be made small, wafer utilization efficiency per area can also be enhanced. It is therefore also possible to reduce fabrication costs. Since the groove formed in the cleavage position designation region can be formed simultaneously with the lens, it is possible to easily enhance yields without increasing a new process.

According to an aspect of the present invention, a groove is provided in advance directly below a desired cleavage position, and the thickness of a wafer is made thin at this position. There is thus provided a structure in which the wafer is easier to break at the desired cleavage position than concave regions densely disposed in row form, which occur with narrow pitching of a device interval. It is therefore possible to easily generate cleavage at a desired position and improve device's fabrication yields. Further, since the yield can be ensured even where the narrow pitching is done, the wafer utilization efficiency per are can be enhanced.

### BRIEF DESCRIPTION OF THE DRAWINGS

FIG. 1A is a sectional view of a horizontal cavity surface emitting laser of a conventional structure as viewed in the direction of its optical axis;

FIG. 1B is a plan view of a horizontal cavity surface emitting laser of a conventional structure;

FIG. 1C is a plan view of a narrow-pitch horizontal cavity surface emitting laser of a conventional structure;

FIG. 2A is a frontside birds-eye view of a horizontal cavity surface emitting laser showing a first embodiment of the present invention;

FIG. 2B is a backside birds-eye view of the horizontal cavity surface emitting laser showing the first embodiment;

FIG. 3A is a sectional view showing a process for manufacturing a horizontal cavity surface emitting laser device according to a first embodiment;

FIG. 3B is a sectional view illustrating a process for manufacturing the horizontal cavity surface emitting laser device according to the first embodiment

FIG. 3C is a sectional view depicting a process for manufacturing the horizontal cavity surface emitting laser device according to the first embodiment;

FIG. 3D is a sectional view showing a process for manufacturing the horizontal cavity surface emitting laser device according to the first embodiment;

FIG. 3E is a sectional view showing a process for manufacturing the horizontal cavity surface emitting laser device according to the first embodiment;

FIG. 3F is a sectional view showing a process for manufacturing the horizontal cavity surface emitting laser device according to the first embodiment;

FIG. 3G is a sectional view showing a process for manufacturing the horizontal cavity surface emitting laser device according to the first embodiment;

FIG. 3H is a plan view showing a process for manufacturing the horizontal cavity surface emitting laser device according to the first embodiment;

FIG. 3I is a sectional view showing a process for manufacturing the horizontal cavity surface emitting laser device according to the first embodiment;

FIG. 4 is a birds-eye view of a horizontal cavity surface emitting laser array showing the first embodiment of the present invention;

FIG. 5A is a frontside birds-eye view of a horizontal cavity surface emitting laser showing a second embodiment of the present invention;

FIG. 5B is a backside birds-eye view of the horizontal cavity surface emitting laser shown in FIG. 5A;

FIG. 6A is a mounting sectional view of a horizontal cavity surface emitting laser array module showing a third embodiment of the present invention, as viewed in the direction parallel to its optical axis;

FIG. 6B is a plan view of a horizontal cavity surface emitting laser array module showing the third embodiment of the present invention;

FIG. 7A is a frontside birds-eye view of a vertical illuminated waveguide photodiode illustrating a fourth embodiment of the present invention; and

FIG. 7B is a backside birds-eye view of the vertical illuminated waveguide photodiode illustrating the fourth embodiment of the present invention.

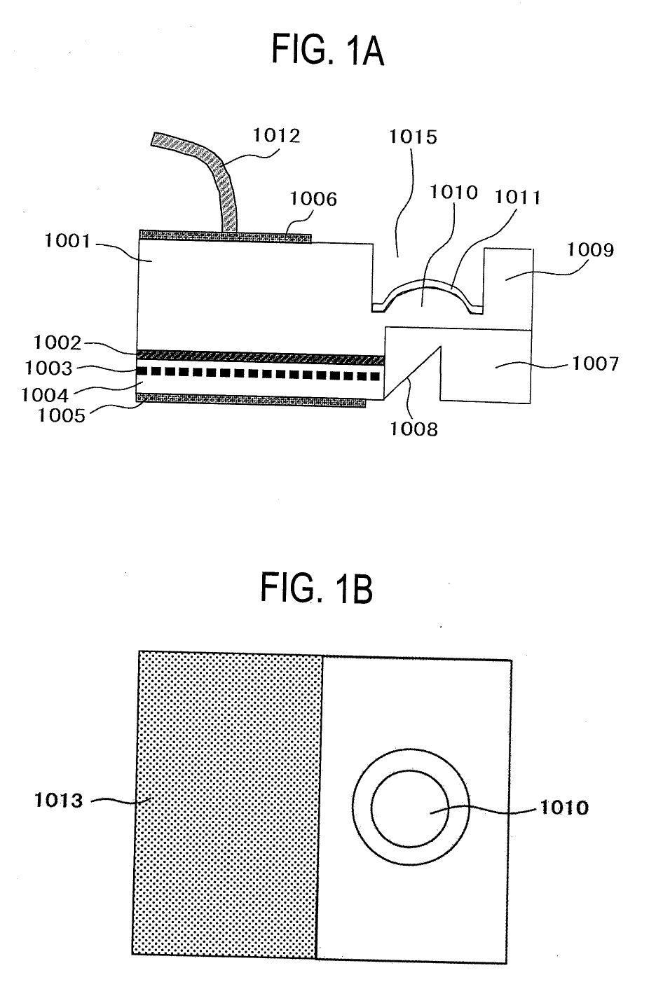

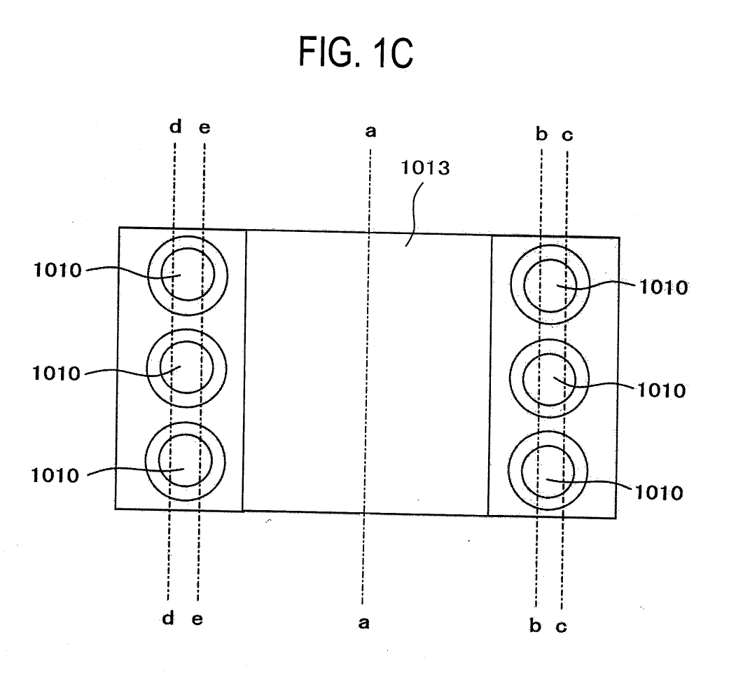

### DETAILED DESCRIPTION OF THE PREFERRED EMBODIMENTS

Exemplary embodiments of the present invention will hereinafter be explained in detail using the accompanying drawings.

### First Embodiment

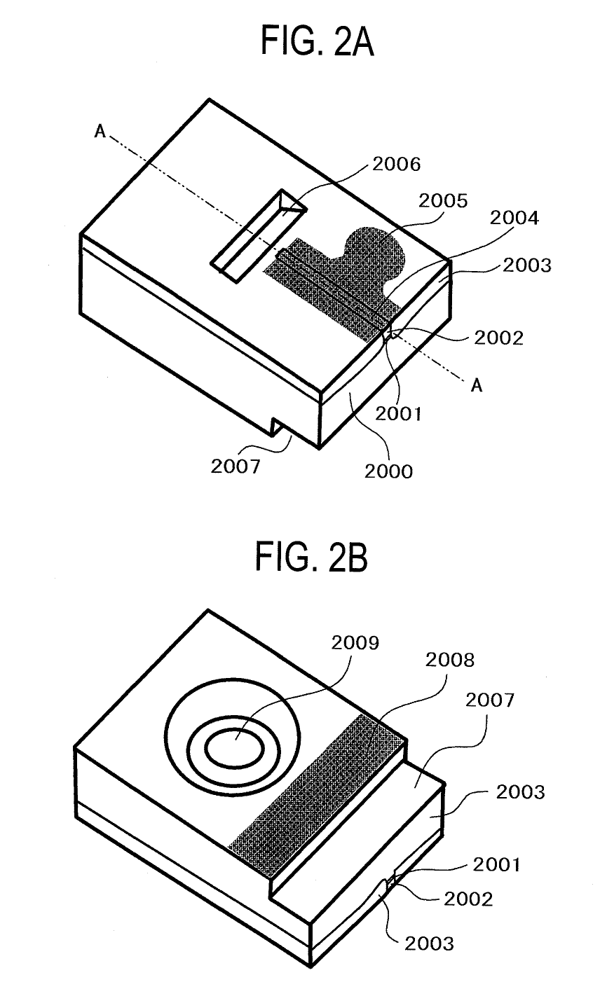

A structure of a horizontal cavity surface emitting laser according to a first embodiment will be explained using FIGS. 2A and 2B, FIGS. 3A through 3F, and FIG. 4. The present embodiment is an example in which the present invention is applied to a 250-μm horizontal cavity surface emitting laser in which a device width (lens interval) is the same value as the pitch of a commercialized ribbon fiber. FIG. 2A is a birds-eye view of the surface of a laser device, and FIG. 2B is a light emitting surface of the laser device. Incidentally, although a chip from which a single channel element is cut out is illustrated in FIGS. 2A and 2B, an array structure is also possible. In the horizontal cavity surface emitting laser according to the present embodiment, an active layer 2001, a p-type semiconductor layer 2002, and a p-type contact layer 2004 are successively stacked and grown over an n-type InP substrate 2000. Further, although not illustrated in the drawing, a diffraction grating layer is directly formed on the active layer 2001. p-doped InP is used for the p-type semiconductor layer 2002. For example, an InGaAlAs-based strained quantum well structure or the like is used for the active layer 2001. GaInAsP or the like is used as for the diffraction grating layer. The horizontal cavity surface emitting laser has a reflector 2006 formed by etching a semiconductor buried layer. At this time, semi-insulating Fe-doped InP is used for the semiconductor embedded layer.

The n-type InP substrate 2000 is formed with a concave-shaped step. Further, an integrated lens 2009 formed by etching the n-type InP substrate 2000 is integrated at the bottom of the step. The surface of the integrated lens 2009 is given reflection-free coating comprised of a thin film of alumina, for example. At this time, a p-type electrode 2005 is formed above the cavity. An n-type electrode 2008 is formed over the n-type InP substrate at a position opposite to the p-type electrode 2005. Since cleavage is done by applying the present invention, a terrace 2007 is formed at a cleavage end surface of the n-type InP substrate.

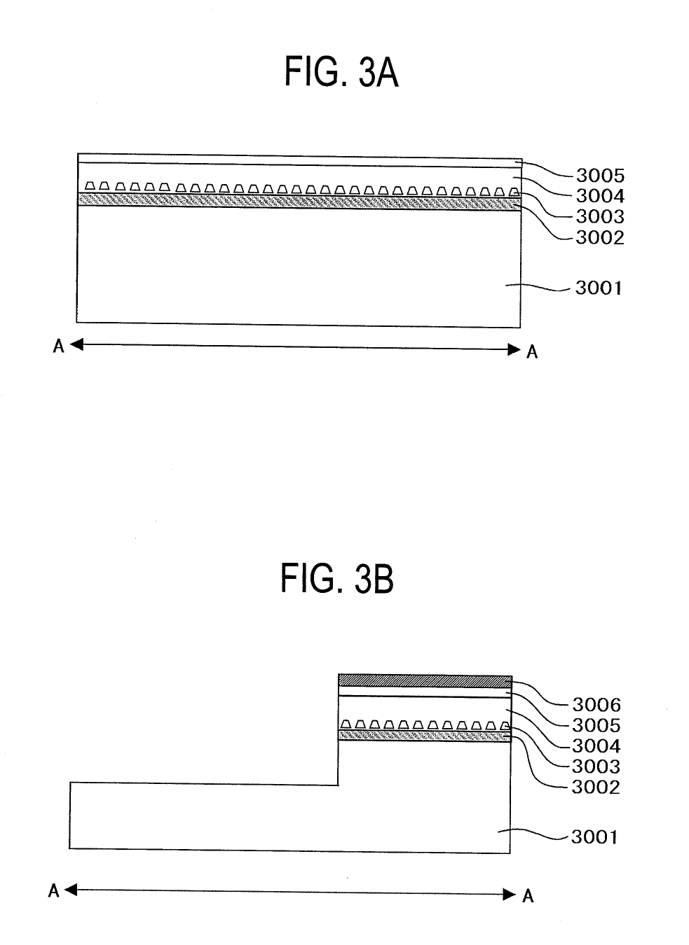

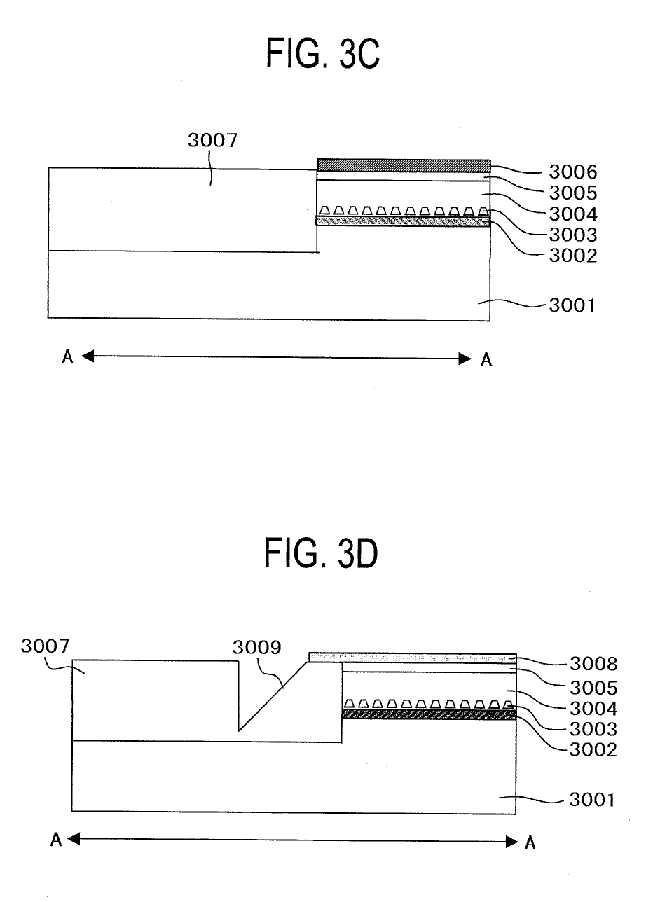

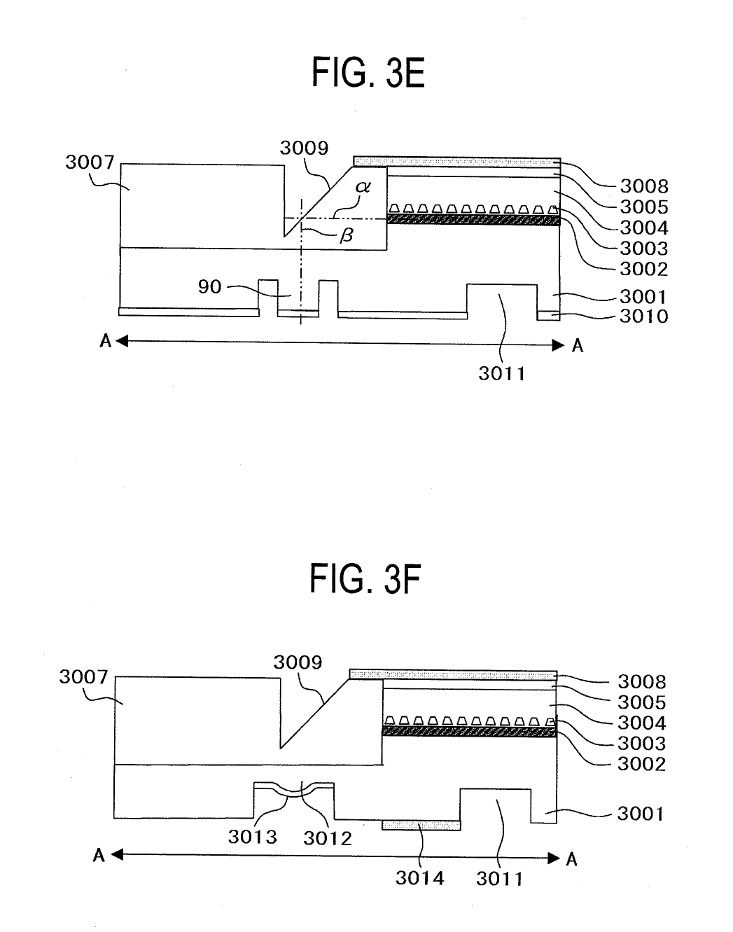

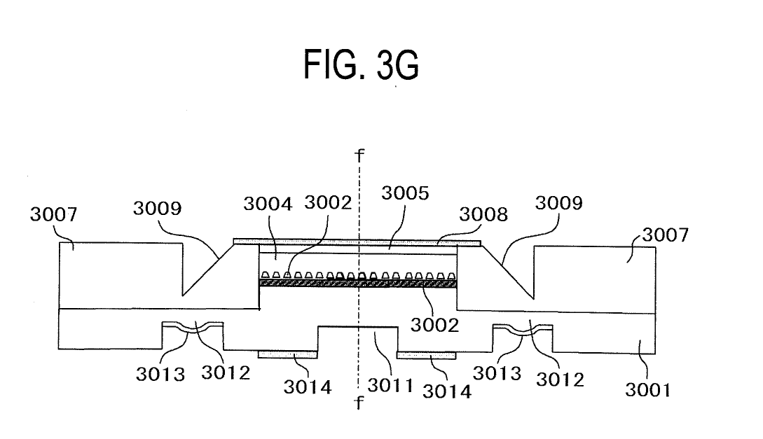

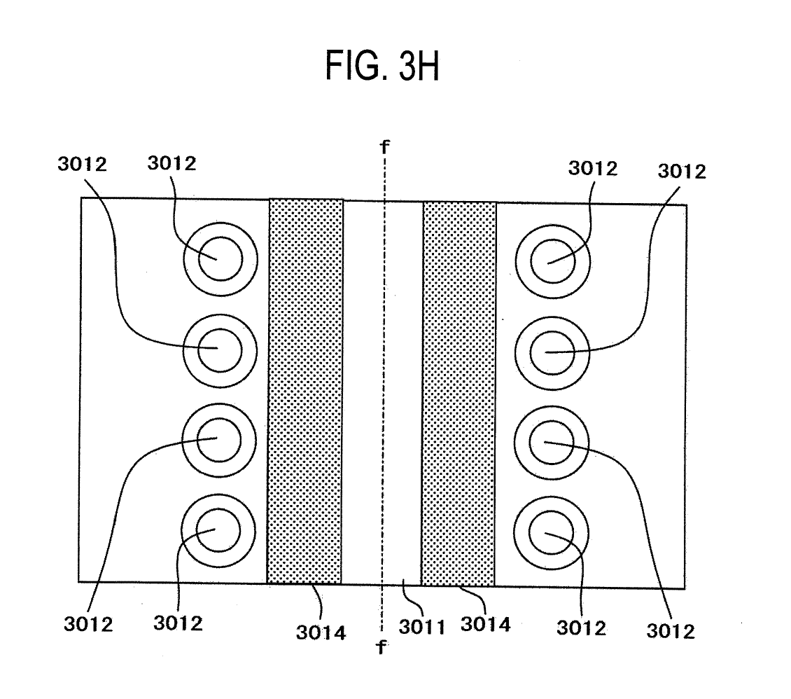

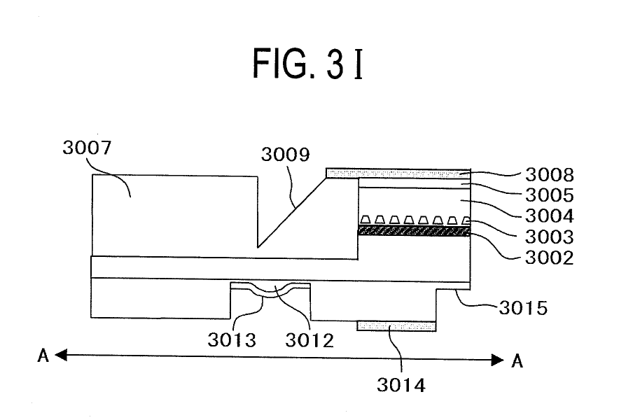

A detailed manufacturing method of the horizontal cavity surface emitting laser to which the present invention is applied, will next be explained using FIGS. 3A through 3F. FIGS. 3A through 3F are respectively sectional views showing manufacturing processes of a horizontal cavity surface emitting laser device shown by a first embodiment. Incidentally, the section thereof is a section taken between A and A shown in FIG. 2A. As shown in FIGS. 3A through 3F, the wavelength 1.3 μm-band InGaAlAs quantum well type horizontal cavity surface emitting laser device according to the present embodiment has a buried hetero (BH) structure in which a semiconductor hetero structure processed in stripe form is buried with a semi-insulating layer. In the present example, the periphery of a stripe-shaped optical waveguide portion at the buried hetero structure is buried with a high-resistance semi-insulating layer 3007 formed by doping InP with Fe (Ferrum). An n-type semiconductor is assumed to be doped with sulfur (chemical symbol S), and a p-type semiconductor is assumed to be doped with zinc (chemical symbol Zn).

FIG. 3A shows a sectional view of a stacked structure in the present embodiment. An active layer 3002 is provided on an n-type InP substrate 3001. Although not shown in the drawing, the active layer 3002 is composed of undoped InGaAlAs between an n-side light confinement layer comprised of n-type InGaAlAs and a p-type light confinement layer comprised of p-type InGaAlAs and has a multi-quantum well structure in which a well layer WL having a thickness of 7 nm and a barrier layer BL having a thickness of 8 nm are stacked in five periods. Such a multi-quantum well structure is designed so as to be able to realize sufficient characteristics as laser. A diffraction grating layer 3003 comprised of an InGaAsP material is provided above the active layer 3002 so as to be embedded in a p-type semiconductor layer 3004 comprised of p-type InP, which functions as a clad layer. Further, a contact layer 3005 comprised of p-type InP is provided thereon. A structure of the active layer 3002 and the diffraction grating layer 3003 is formed in such a manner that the oscillated wavelength of a DFB laser at room temperature becomes 1310 nm.

An optical waveguide function is generated by holding the active layer 3002 with a clad layer lower in refractive index than it. The optical waveguide function is achieved by a stacked structure of a clad layer/active layer/clad layer. In a concrete form, however, light confinement layers are provided with a quantum well layer interposed therebetween to enhance light confinement at the active layer. As a matter of course, the refractive index of the clad layer is lower in value than that of the light confinement layer. Incidentally, in the present embodiment, the n-type InP substrate 3001 acts as a first semiconductor layer that functions as a clad layer.

The polarity of the diffraction grating layer 3003 is set as a p type. Such a structure is called refractive-index coupled DFB laser because only the refractive index periodically changes in an optical propagation direction. Incidentally, although the present embodiment has explained where the diffraction grating layer 3003 is uniformly formed over the whole region of the DFB laser, a so-called phase shift structure configured at part of its region with the phase of a diffraction grating being shifted, may be provided as needed. Although the present embodiment is configured by the DFB laser, a DBR laser may be adopted.

Manufacturing processes of the horizontal cavity surface emitting laser device according to the present embodiment will next be explained using FIGS. 3A through 3F.

First, in order to form a structure of a laser portion as shown in FIG. 3A, an active layer 3002 comprised of InGaAlAs, which is made up of a light confinement layer comprised of n-type InGaAlAs, a strained multi-quantum well layer comprised of InGaAlAs, and a light confinement layer comprised of p-type InGaAlAs, is formed on an n-type InP substrate 3001.

Next, a semiconductor multilayered body including a diffraction grating layer 3003 comprised of InGaAsP is formed above the active layer 3002. Further, a p-type semiconductor layer 3004 (clad layer) comprised of p-type InP is formed thereabove. Next, a contact layer 3005 comprised of p-type InGaAs is formed. A carrier concentration based on doping is set to 10¹⁸ cm⁻³ with respect to both n and p types. A silicon dioxide film is coated on an InP wafer having such a multilayer structure to function as a protective mask. Although not shown in the drawing, etching is done up to parts of the contact layer, p-type clad layer 3004, diffraction grating layer 3003, active layer 3002 and n-type InP substrate 3001 using the silicon dioxide mask to thereby form an optical waveguide (refer to FIG. 3B). As the etching, for example, any technique may be used like dry etching such as reactive ion etching (RIE) using a chlorine gas, or wet etching using a bromine solution or the like, and a combination of the two.

Next, as shown in FIG. 3B, a patterning mask is formed in an embedded growing region using a silicon oxide film 3006. A semiconductor is not grown in the region covered with the silicon oxide film 3006 upon the embedded growth. It is thus possible to arbitrarily form a portion where a buried layer is grown and a portion where no buried layer is grown, using the patterning mask. This time, the patterning film is formed so as to cover a portion at which a waveguide layer is not formed.

Next, as shown in FIG. 3C, the present sample is carried in a crystal growth furnace to bury and grow a semi-insulating layer 3007 comprised of InP doped with Fe at 600° C. using a MOVP method. The buried hetero structure is formed by this etching process and the process of re-growing the buried layer. The buried hetero structure is a structure in which both sides of the optical waveguide in a light traveling direction are buried with a light confineable material. As the material used for confinement, a high-resistance material is normally used. In the present example, the semi-insulating layer 3007 comprised of the high-resistance InP doped with Fe is used. Incidentally, in the buried structure forming process, both left and right sides of the optical waveguide as viewed in the light traveling direction are embedded and at the same time the end on the light emitting side of the optical waveguide is also buried with the semi-insulating layer 3007. The reason why the tip of the optical waveguide is buried with InP is that a portion at which a 45° tilt mirror is subjected to etching processing can be made up of only an InP material (Fe—InP) by doing so, and it becomes easy to perfectly and smoothly process the mirror formed by etching.

Thereafter, as shown in FIG. 3D, the silicon dioxide film 3006 used as the selection growth mask for embedded growth is removed to form a silicon nitride film (not shown) for an etching mask. The semi-insulating layer 3007 comprised of InP, which has been doped with Fe, is etched at a tilt angle of 45° to form a reflector 3009. Chemically assisted ion beam etching using chlorine and an argon gas is used for this tilt etching, and a wafer is etched with being tilted at an angle of 45°, whereby etching of 45° is realized. Incidentally, although the present embodiment has described the etching method using CAIBE, reactive ion beam etching (RIBE) using a chlorine gas, or wet etching may be used. The shape of a section in an optical axis direction, of the reflector 3009 is shaped in the form of the character “re” in the katakana characters, but may be even a V type. Further, a structure comprised of only a slope is also possible.

Next, after removal of the silicon nitride film, a p electrode 3008 (p-type electrode) is evaporated onto the p-type InGaAs contact layer 3005. Further, the back surface of the substrate is polished to a thickness of 150 μm and thereafter a silicon nitride mask 3010 is formed on the back surface of the substrate.

Subsequently, as shown in FIG. 3E, it is etched to a circular shape having a diameter of 125 μm and a depth of 30 μm by reactive ion etching using a mixed gas of methane and hydrogen. At this time, the silicon nitride mask 3010 is formed in such a manner that the position of the center of the columnar circle intersects with a vertical line (β) that drops directly below from a point where an extension line (α) of the active layer 3002 and the 45° tilt mirror intersect. Incidentally, the shape of the circle may be an elliptical shape according to the uses. Simultaneously at this time, as shown in FIG. 3E, a cleavage direction (i.e., direction orthogonal to an optical axis) groove 3011 is formed in the n-type InP substrate at the position where its cleavage end surface is formed. At this time, the width (length in the optical axis direction) of the groove 3011 is set as 60 μm, and the depth thereof is set as 30 μm identical to the columnar shape.

Subsequently, as shown in FIG. 3F, the silicon nitride mask 3010 is removed and the silicon nitride mask lying above a columnar portion 90 surrounded by a portion dug in doughnut form is removed, followed by execution of wet etching. Thus, the columnar portion is etched from its surface so that the corners are removed, whereby a backside InP lens 3012 is formed. Incidentally, the surface of the backside InP lens is covered with a reflection-free film 3013 in a subsequent process. Since the convex lens is formed in a beam outgoing or emitting surface, a beam narrow in radiation angle and high in parallelism can be obtained.

Next, pattering is performed on the n-type InP substrate with a resist to evaporate an n-type electrode 3014. Two devices adjacent in the direction of the optical axis of the horizontal cavity surface emitting laser made up in accordance with the processes shown so far are illustrated in FIG. 3G. In the present embodiment, as shown in FIG. 3H, the devices are disposed so as to share a position f-f where a cleavage end surface is formed later.

Next, cleavage is done in a predetermined cleavage region f-f extending along the groove 3011, so that a bar-like formative body in which the devices are arranged in the direction orthogonal to the optical axis, is fabricated. At this time, an end surface formed in the cleavage is configured to be a (100) crystal plane of InP. A sectional view in the optical axis direction, of the bar-like formative body at this time is illustrated in FIG. 3I. With the application of the present invention, a terrace 3015 is formed on the n-type InP substrate at the cleavage position of the bar-like formative body. With the application of the present invention, a bar-like formative body can be fabricated with high yield in a structure in which a device width is narrow-pitched like 250 μm without making any cleavage at the concave portion formed with the lens at the cleavage. The number of device acquisitions per wafer area can also be enhanced to about 1.6 times or so the conventional number, and a device effective even in reducing costs can be fabricated.

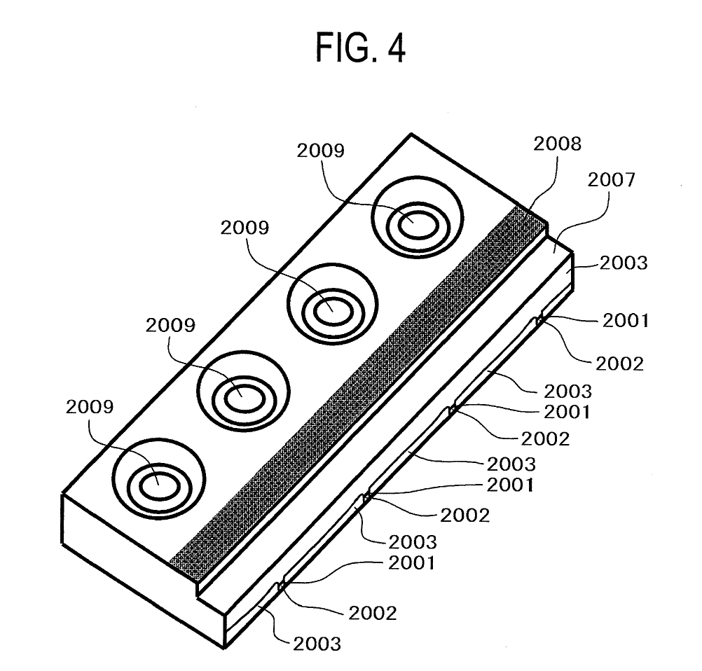

Thereafter, although not shown in the crystal plane formed by cleavage, a high reflective film comprised of a stacked structure of amorphous silicon and alumina is formed. Afterwards, chipping is performed every predetermined channel. A birds-eye view of a 4-channel array-type lens integrated horizontal cavity surface emitting laser fabricated by the above processes is shown in FIG. 4.

The horizontal cavity surface emitting laser device of the present embodiment is capable of obtaining, by virtue of the effect of lens integration, a narrow outgoing beam whose beam expansion angle is 2° and which is formed as a circular beam spot having a diameter of 120 μm at a position of 100 μm as viewed from its laser backside. As described above, an array laser having a narrow pitch suitable for high density integration and a narrow beam expansion angle can be fabricated with satisfactory yields.

Incidentally, although the present embodiment has shown an example applied to the 1.3 μm wavelength-band InGaAlAs quantum well type laser formed on the InP substrate, the material for the substrate, the material for the active layer and the oscillated wavelength are not limited to this example. The present invention is applicable similarly even to, for example, another material system such as a 1.55 μm-band InGaAsP laser or the like.

Although the embodiment having the BH structure has been shown above, the present invention is applicable even to a ridge wave guide (RWG) type structure.

### Second Embodiment

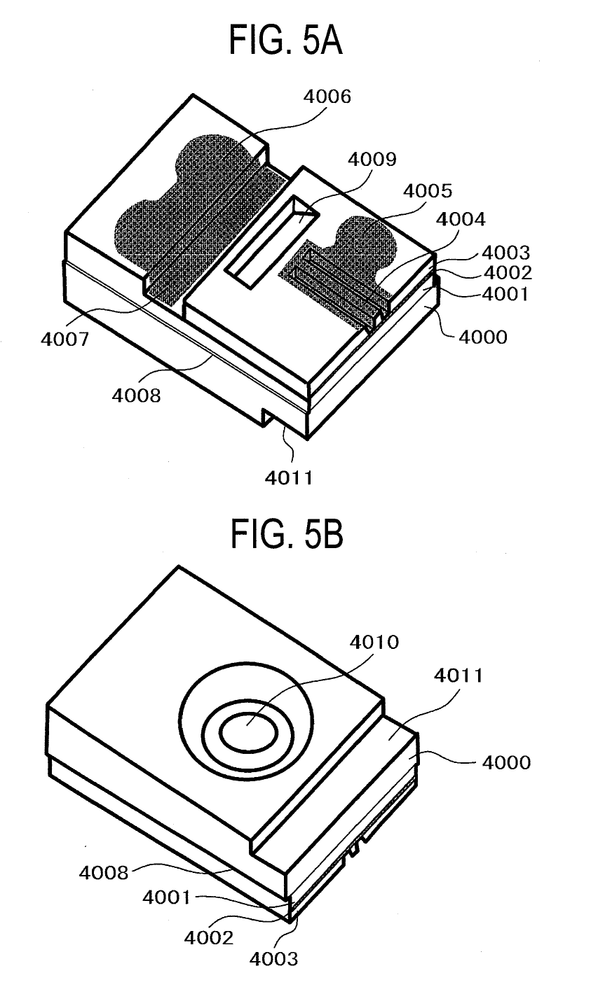

The present embodiment is an example applied to a 1.3 μm-band InGaAlAs quantum well type horizontal cavity surface emitting laser having an RWG-type flip-chip mounted structure with a device width of 250 μm. FIG. 5A is a birds-eye view showing the surface of a laser device, and FIG. 5B is a light emitting surface of the laser device. In the horizontal cavity vertically emitting laser according to the present embodiment, an n-type semiconductor layer 4001, an active layer 4002, a p-type semiconductor layer 4003, and a contact layer 4004 are successively stacked and grown over an Fe-doped semi-insulating semiconductor substrate 4000. Further, although not shown in the drawing, a diffraction grating layer is formed directly on the active layer 4002. n-doped InP is used for the n-type semiconductor layer 4001, p-doped InP is used for the p-type semiconductor layer 4003, and a strained quantum well structure of InGaAlAs or the like, for example is used for the active layer 4002. GaInAsP or the like is used as for the diffraction grating layer. The horizontal cavity vertically emitting laser has a reflector 4009 formed by etching a semiconductor buried layer. At this time, an electrical isolation layer 4008 between elemental devices is simultaneously formed. Since the present embodiment is of an RWG type, as shown in FIG. 5 A, the p-type semiconductor layer 4003 lying directly on the resonator or cavity has a ridge shape etched to a concave-type stripe shape. A p-type electrode 4005 is formed above the ridge shape. Aside from this, the p-type semiconductor layer 4003 and the active layer 4002 are dug to reach the n-type semiconductor layer 4001 to form an n-type electrode 4006 with the exposed n-type semiconductor layer taken as an n-type contact layer 4007. As shown in FIG. 5B, a lens similar to the first embodiment is formed at the back surface of the semi-insulating semiconductor substrate 4000. At this time, in a manner similar to the first embodiment, a groove is formed on the semi-insulating substrate 4000 including a cleavage position in the direction orthogonal to the optical axis. Thereafter, cleavage is done along the formed groove to form a high reflection film in a formed crystal plane although not shown in the drawing, in a manner similar to the first embodiment. Incidentally, although FIGS. 5A and 5B illustrate the case in which the horizontal cavity vertically emitting laser is configured as a single channel device, an array structure may also of course be adopted. Even when the lens-integration type horizontal cavity vertically emitting laser having the flip-chip mounted structure is brought into narrow chipping (shortened in device width) by the above processes, the device can be fabricated with satisfactory cleavage yields. In the RWG-type laser, current can locally efficiently be injected via the ridge shape portion at the section of the active layer as viewed in the cavity vertical direction. Since light is generated only from the portion in which the current has been injected, light confinement at the section as viewed in the cavity vertical direction is also achieved simultaneously. Further, since such a current leak to the lateral portion of the active layer as to significantly appear in the BH structure does not occur either under a high temperature, an operation in a wide temperature range is made possible.

### Third Embodiment

The present embodiment is a configuration example where an array-type lens integration horizontal cavity vertically emitting laser fabricated by applying the present invention thereto is applied to a small module.

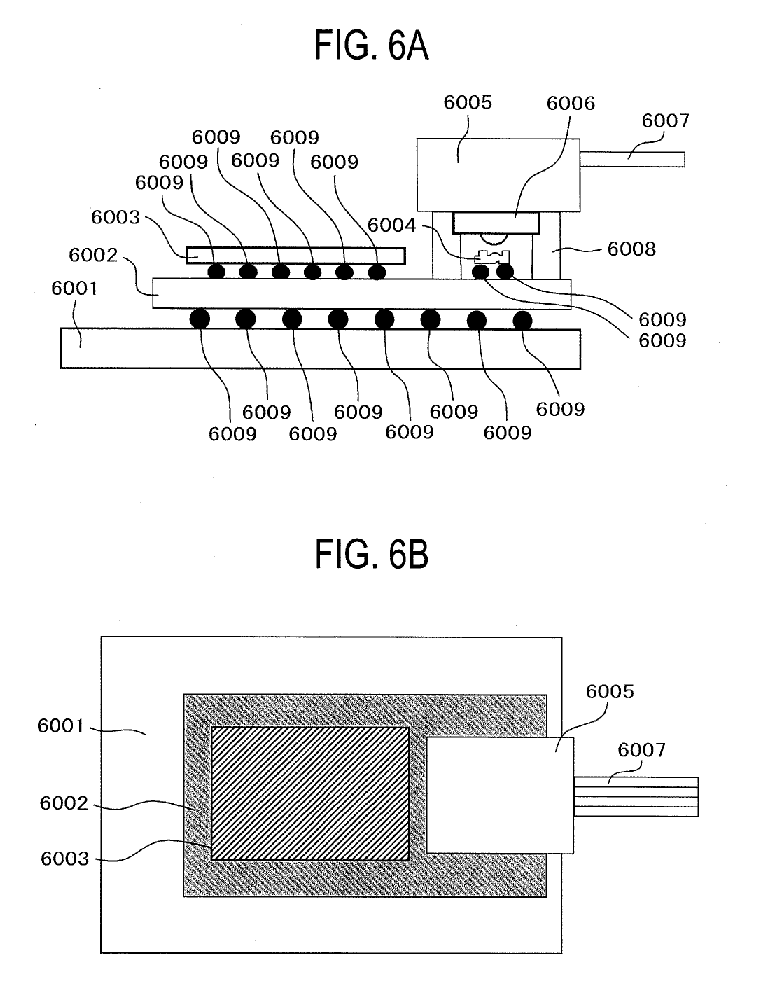

FIG. 6A is a sectional view taken along a device optical-axis direction, of a module, and FIG. 6B shows a top view of the module. In the module according to the present embodiment, a multilayer wiring ceramic substrate 6002 is mounted over a package substrate 6001 having a strip line by gold bumps 6009. Further, an integrated circuit 6003 for driving the laser, and a 4-channel lens integration type horizontal cavity vertically emitting laser array 6004 having a flip-chip mounted structure fabricated by applying the present invention thereto are mounted over the multilayer wiring ceramic substrate 6002 while being electrically connected to each other by gold bumps. Further, a fiber array connector 6005 to which a lens array 6006 is mounted, is mounted above the laser array 6004 by column members 6008 at a position having the optimum optical coupling. A pitch interval of a ribbon fiber 6007 connected to the fiber array connector is set to 250 μm. In order to match with it, each channel interval of the laser array is also set to 250 μm. At this time, a lens integrated on the light emitting surface of the laser array 6004 is integrated on the bottom of a concave portion that forms a circle concentric with the lens, in a manner similar to the first embodiment.

In terms of the optical coupling, the diameter of the concave portion is set to 200 μm, and the diameter of the lens is set to 100 μm. In this case, the interval between the adjacent concave portions becomes as extremely small as 50 μm, but the device can be fabricated with satisfactory yields by application of the present invention. High-efficient optical coupling can be realized simultaneously on the four channels by using the so-fabricated device.

Using the present module enables transmission of a signal of 100 Gbps in total for the four channels constituted of 25 Gbps per channel. A small optical module suitable as for within a router device can be fabricated by using the laser array to which the present invention is applied.

### Fourth Embodiment

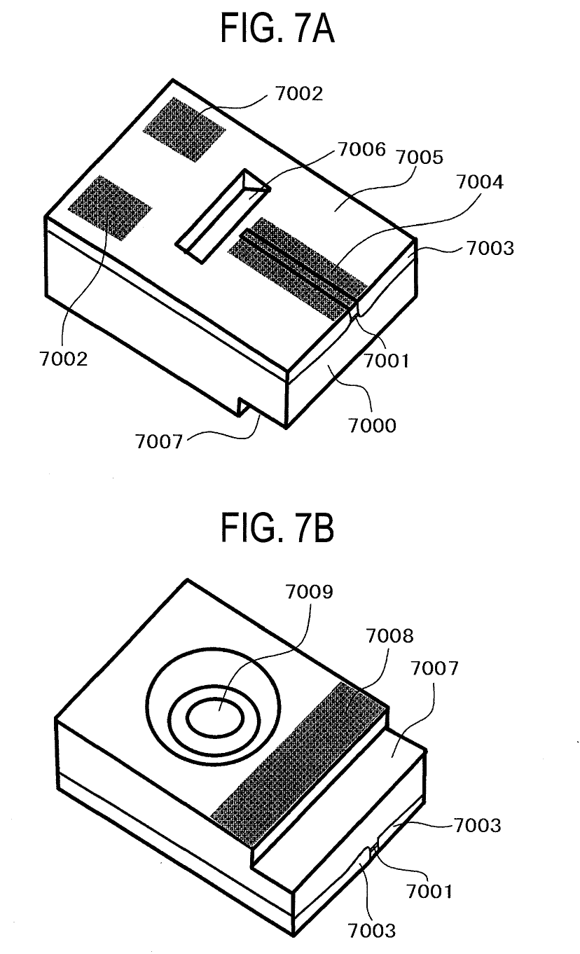

The present embodiment is an example in which the present invention is applied to a vertical illuminated waveguide photodiode. FIG. 7A is a birds-eye view of the surface of a device, and FIG. 7B is a light incident plane thereof. A method of fabricating the waveguide type photodiode according to the present embodiment will hereinafter be explained.

First, a first clad layer comprised of InAlAs, a first core layer comprised of InGaAlAs and an absorption layer 7001 comprised of InGaAs although not shown in the drawings, and a second core layer comprised of InGaAlAs, a second clad layer comprised of InAlAs and a contact layer comprised of InGaAs although not shown in the drawings are grown over an n-type InP substrate 7000 in this order using metal organic chemical vapor deposition. Next, etching is done up to parts of the first clad layer, first core layer, absorption layer, second core layer, second clad layer, contact layer and n-type InP substrate to thereby form a ridge shape having a length of 100 μm and a width of 10 μm. As the etching, for example, any technique may be used like dry etching such as reactive ion etching (RIE) using a chlorine gas, or wet etching using a bromine solution or the like, and a combination of the two. Subsequently, the peripheral portion of the ridge shape is buried with a buried semi-insulating layer 7003 comprised of Fe-doped InP. Thereafter, a reflector 7006 is formed ahead of the tip portion of the ridge shape by etching. Afterwards, although not shown in the drawing, a protective film 7005 comprised of SiN is formed in the surface of a wafer, and SiN of part of the upper portion of the ridge shape is removed. Thereafter, a p electrode 7004 is formed on a ridge stripe. At this time, a stud p electrode 7002 is simultaneously formed to prevent a tilt at mounting. Next, a lens 7009 is formed in the n-type InP substrate 7000.

As shown in FIG. 7B, a lens similar to the first embodiment is formed at the back surface of the semi-insulating semiconductor substrate 7000. At this time, in a manner similar to the first embodiment, a groove is formed on the semi-insulating substrate 7000 including a cleavage position in the direction orthogonal to an optical axis. Subsequently, an n-type electrode 7008 is formed and finally a reflection-free coat comprised of an alumina single layer film is applied onto the lens 7009 although not shown in the drawing. Thereafter, cleavage is performed along the formed groove. A terrace 70007 is formed in a post-cleavage chip by using the present invention.

Incidentally, although FIGS. 7A and 7B illustrate the case where the present embodiment is configured as a single channel device by chipping, an array structure may of course be adopted. Even when a lens integration type horizontal cavity vertically emitting laser having a flip-chip mounted structure is narrow-chipped (shortened in device width) by the above processes, a device can be fabricated with satisfactory cleavage yields.

In the waveguide type photodiode fabricated as described above, light incident via the lens 7009 in the direction perpendicular to the n-type InP substrate 7000 is optical path-converted 90° in a substrate in-plane direction by the reflector 7006 and introduced into a stripe-like absorption layer. The waveguide type photodiode fabricated in accordance with the above procedures has achieved a conversion efficiency of 0.8 W/A, a modulation band of 30 GHz and an operation at 25 Gbps.

While the invention made above by the present inventors has been described specifically on the basis of the preferred embodiments, the present invention is not limited to the embodiments referred to above. It is needless to say that various changes can be made thereto within the scope not departing from the gist thereof.

What is claimed is:

1. A horizontal cavity surface emitting laser comprising:
a cavity structure portion including a stacked structure of a first conduction type clad layer, an active layer for generating light and a second conduction type clad layer stacked over a semiconductor substrate in this order, the cavity structure portion causing the generated light to be reflected or resonated in an in-plane direction;
an optical waveguide layer that is formed on the semiconductor substrate and guides the light generated from the active layer;
a total reflection mirror formed at a part of the optical waveguide layer, for reflecting the light radiated from the cavity structure portion and emitting the light from a back surface of the semiconductor substrate; and
a condensing lens that is integrated into a light emitting region of the semiconductor substrate, and which focuses the light reflected from the mirror,
wherein the back surface of the semiconductor substrate has a groove with the condensing lens integrated at the bottom thereof, and a terrace-like portion formed parallel to the cleavage direction of the semiconductor substrate, and
wherein the terrace-like portion is formed within a range in which a forming region of the cavity structure portion is extended downward, and has an open end on the cleaving facet side of the semiconductor substrate, a sidewall formed on the opposite side of the open end, and a terrace shape with the cleavage direction taken as a longitudinal direction thereof.

2. A horizontal cavity surface emitting laser according to claim 1, wherein the groove has a concave shape provided so as to surround a peripheral portion of the light emitting region, and the condensing lens is provided at the bottom lying inside the groove.

3. A horizontal cavity surface emitting laser according to claim 1, wherein the depth of the terrace-like portion is deeper than the depth of the groove.

4. A horizontal cavity surface emitting laser according to claim 1, wherein the depth of the terrace-like portion is shorter than a path length that connects a reflection point where the light emitted from the active layer is reflected by the reflector, and an incident point of the surface of the condensing lens on which the reflected light falls.

5. A horizontal cavity surface emitting laser according to claim 1, wherein the sidewall of the terrace-like portion is provided so as to form a tapered shape having a predetermined angle with respect to the direction substantially parallel to the surface of the semiconductor substrate.

6. A horizontal cavity surface emitting laser according to claim 1, wherein a sectional shape of the terrace-like portion is formed in a V-shaped fashion.

7. A horizontal cavity surface emitting laser according to claim 1, wherein a section in a light resonance direction, of the reflector has a tapered shape at least on the cavity structure portion side.

8. A horizontal cavity surface emitting laser array wherein at least two the horizontal cavity surface emitting lasers according to claim 1 are placed side by side over a semiconductor substrate in a direction orthogonal to a light resonance direction thereof.

9. A horizontal cavity surface emitting laser array according to claim 8, wherein when planar shapes of concave portions provided in adjacent the lasers are circular, an intercentral interval between the concave portions is not greater than the diameter of each of the concave portions.

10. A vertical illuminated waveguide photodiode including a stacked structure of a first conduction type clad layer, an absorption layer for absorbing light and a second conduction type clad layer provided over a semiconductor substrate, which are stacked in this order, the vertical illuminated waveguide photodiode comprising:
a waveguide layer that is provided at least part of the semiconductor substrate and guides the light launched into the semiconductor substrate;
a reflector that changes an optical path of the light incident from the back surface of the semiconductor substrate and launches the light into the absorption layer; and
a condensing lens that is provided in a light incident region that corresponds to the back surface of the semiconductor substrate and causes the light to fall thereon, and which focuses the incident light,
wherein the back surface of the semiconductor substrate has a groove with the condensing lens provided at the bottom thereof, and a terrace-like portion provided along the direction of cleavage of the semiconductor substrate, and
wherein the terrace-like portion is disposed within a range in which a forming region of the absorption layer is extended downward, and has an open end on the lateral end side having a crystal plane formed by cleavage of the semiconductor substrate, a sidewall provided on the side opposite to the open end, and a terrace shape with the cleavage direction taken as a longitudinal direction thereof.

11. A vertical illuminated waveguide photodiode according to claim 10, wherein the groove has a concave shape provided so as to surround a peripheral portion of the light incident region, and the condensing lens is provided at the bottom lying inside the groove.

12. A vertical illuminated waveguide photodiode according to claim 10, wherein the depth of the terrace-like portion is deeper than the depth of the groove.

13. A vertical illuminated waveguide photodiode according to claim 10, wherein the depth of the terrace-like portion is shorter than a path length that connects an incident point of the surface of the condensing lens on which the light falls, and a reflection point where the incident light is reflected by the reflector.

14. A vertical illuminated waveguide photodiode according to claim 10, wherein the sidewall of the terrace-like portion is provided so as to form a tapered shape having a predetermined angle with respect to the direction substantially parallel to the surface of the semiconductor substrate.

15. A vertical illuminated waveguide photodiode according to claim 10, wherein a sectional shape of the terrace-like portion is formed in a V-shaped fashion.

16. A vertical illuminated waveguide photodiode according to claim 10, wherein a section in a light resonance direction, of the reflector has a tapered shape at least on the absorption layer side.

17. A vertical illuminated waveguide photodiode array wherein at least two the vertical illuminated waveguide photodiodes according to claim 10 are placed side by side over a semiconductor substrate in a direction orthogonal to a light propagation direction thereof.

18. A vertical illuminated waveguide photodiode array according to claim 17, wherein when planar shapes of concave portions provided in adjacent the vertical illuminated waveguide photodiodes are circular, an intercentral interval between the concave portions is not greater than the diameter of each of the concave portions.

19. A method of manufacturing a horizontal cavity surface emitting laser, comprising:
preparing a semiconductor substrate;
stacking a first conduction type clad layer, an active layer for generating light and a second conduction type clad layer over the semiconductor substrate in this order and thereby forming a cavity structure portion for causing the light generated from the active layer to be reflected or resonated in an in-plane direction;
forming an optical waveguide layer for guiding the light at least a part of the semiconductor substrate;
forming a reflector for reflecting the light radiated from the cavity structure portion and emitting the light from the back surface of the semiconductor substrate, at a part of the optical waveguide layer;
forming a condensing lens for focusing the light reflected from the reflector in a light emitting region that corresponds to the back surface of the semiconductor substrate and causes the light to be emitted therefrom; and
providing a groove within a range in which a forming region of the cavity structure is extended downward, and along a cleavage direction within a range including a cleavage position designation region having a predetermined direction capable of cleaving the semiconductor substrate,
wherein cleavage is performed in the cleavage position designation region to thereby separate the semiconductor substrate into at least two and form crystal planes in respective side surfaces of the separated semiconductor substrates.
